(19) United States
(12) Patent Application Publication
(10) Pub. No.: US 2005/0078533 A1
(43) Pub. Date: Apr. 14, 2005

(54) Physiological data recording apparatus for single handed application

(76) Inventors: Andrey Vyshedskiy, Boston, MA (US); William Kania, Westborough, MA (US); Raymond Murphy, Wellesley, MA (US)

Correspondence Address: Andrey Vyshedskiy;Suite 4990, 1153 Centre St., Boston, MA, 02130, US

(21) Appl. No.: 10/682,255

(22) Filed: Oct. 10, 2003

(51) Int. Cl. G11C 7/00

(52) U.S. Cl. 365/200

(57) ABSTRACT

The invention disclosed herein simplifies application of physiological sensors to the body. In the preferred embodiment the plurality of physiological sensors are physically attached to the back of a personal digital assistant (PDA). An operator presses the PDA single-handedly against patient's chest in such a manner that sensors are in contact with patient's skin and the PDA display faces the operator. Physiological signals are then visualized on the PDA screen. The sensors include EKG electrodes and acoustic sensors. The “EKG Stethoscope” is used to simultaneously record the audio signal from an acoustic sensor and the corresponding electrical EKG signal from EKG electrodes. The PDA analyzes EKG and acoustic signals. Further, sound from one acoustic sensor is amplified and transmitted to operator's headphones for simultaneous auscultation. Concurrent audio and visual experience greatly enhances the operator's ability to diagnose lung and heart disease. A plurality of acoustic sensors is used to localize intrathoracic sound origin. The operator looks at the PDA display for cues on abnormal sound location and sound characteristics.

### FIELD OF THE INVENTION

The invention relates to systems used for physiological data acquisition. It also relates to diagnostic systems.

### BACKGROUND OF THE INVENTION

Phonocardiogram recording involves an acoustic sensor placed on a patient's chest and a recording unit. The U.S. Pat. No. 5,213,108 to Mark S Bredesen discloses a visual display stethoscope for use in the auscultation of body sounds. The stethoscope chest piece and recording/visualization unit are physically separated and have to be held by both hands. The chest piece has to be pressed against the patient's chest by one hand while the recording/visualizsation unit has is held in the other hand. The procedure is quite cumbersome.

The problem of sensors application exacerbates when more than one sensor have to be applied concurrently. U.S. Pat. Nos. 5,165,417, 5,844,997, 6,139,505, 6,394,967 to Raymond Murphy, the inventor herein, disclose multichannel sound recording system. The U.S. Pat. No. 5,844,997 to Raymond Murphy discloses method and apparatus for locating the origin of intrathoracic sounds when sounds on the chest are recorded with 5 or more acoustic sensors applied concurrently. Application of multiple sensors to a patient's chest is a challenging problem. All sensors have to endure right amount of pressure against the skin. The pressure is normally provided by the operator's hands. The sensors are wired to the computer. The wires reduce the patient mobility and interfere with EKG leads and intravenous lines. Finally, operation of the computer located away from the patient and simultaneously pressing sensors against the patient's chest is difficult for a single person to accomplish.

### BRIEF SUMMARY OF THE INVENTION

The invention disclosed herein simplifies application of physiological sensors. In the preferred embodiment, referred hereafter as “EKG Stethoscope”, the disclosed system is used to simultaneously record the audio signal from an acoustic sensor and the corresponding electrical EKG signal from EKG electrodes. In other words, the EKG Stethoscope allows the medical practitioner to perform auscultation and obtain electrocardiographic signal at the same time.

The EKG Stethoscope has the following advantages:
A phonocardiogram can be visualized simultaneously with an electrocardiographic signal.
Auscultation of heart sounds is greatly facilitated by knowing the event of the heart cycle visualized on the EKG.
Automatic, that is computer based, heart sound analysis is facilitated by identification of events on the electrocardiogram.

In an alternative preferred embodiment the plurality of acoustic sensors are physically attached to the back of a PDA. An operator presses the PDA single-handedly against patient's chest in such a manner that sensors are in contact with the patient's skin and the PDA display faces the operator. The physiological acoustic signal is converted by the sensors into an electrical signal that is transmitted into the PDA. The PDA automatically analyzes the sound and localizes the origin of the sound. The PDA visualizes the sound waveform, marks sound features and visualizes sound origin on the computer's display. Further, sound from one sensor is amplified and transmitted to operator's headphones for simultaneous auscultation. Concurrent audio and visual experience greatly enhances the operator's ability to diagnose lung and heart disease. The operator looks at the PDA display for cues on abnormal sound intrathoracic location and sound characteristics. The device can characterize abnormal heart sounds such as murmurs and indicate murmur location within the heart. The device can also characterize abnormal lung sounds such as wheezes and crackles and indicate their location within the lungs.

Users working in noisy environments have difficulty with normal stethoscopes. This invention provide important sound information is such noisy environments.

### BRIEF DESCRIPTION OF THE DRAWING

FIG. 1 shows application of the disclosed invention to the patient's chest;

FIG. 2 shows a system for implementing a preferred embodiment of the present invention the EKG Stethoscope;

FIG. 3 shows a system for implementing an alternative preferred embodiment of the present invention a multichannel sound analyzer.

### DETAILED DESCRIPTION OF THE INVENTION

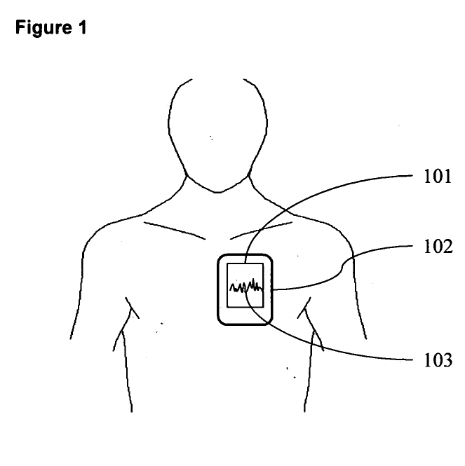

FIG. 1 shows application of the disclosed invention to the patient's chest. The personal digital assistant (PDA) 102 is pressed against patient's chest. Sensors on the back of the PDA are in contact with the skin. The PDA display 101 is facing the operator. Phonocardiogram 103 is visualized on the display.

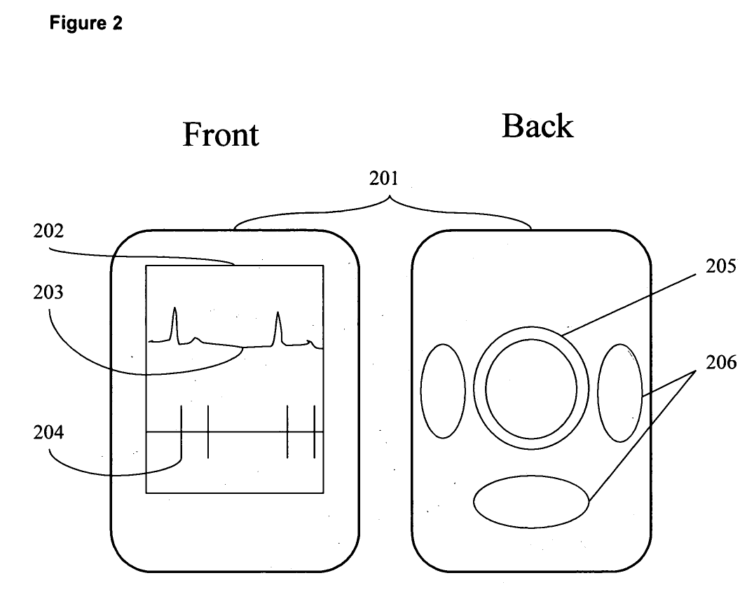

FIG. 2 shows EKG Stethoscope with three EKG electrodes 206 mounted around the chest piece 205. The physician can move the EKG Stethoscope around the chest to collect data at different sites. Suitable EKG electrodes can be made of electroconductive material and have an area of 1 cm². The sound amplification can be either electronic via wire or acoustic via tubing connected to on the one side to the chest piece and on the other to the operator's ears. The microphone suitable for the electronic sound amplification can be an omnidirectional electret microphone embedded into the chest piece 205. The EKG Stethoscope allows a medical practitioner to avoid application of separate EKG electrodes.

The pocket computer 201 of the EKG Stethoscope can be a PDA such as Compaq iPAQ5450 Pocket PC. The electrical signal from both acoustic and EKG sensors is transmitted to the PDA's serial or analog input ports. The transmission can be via wires or wirelessly. The PDA is programmed to display the EKG waveform 203 and Phonocardiogram 204 on its screen 202 and store the data for later retrieval/transfer. Also, the PDA can be programmed to perform the automatic analysis of the EKG and acoustic signals.

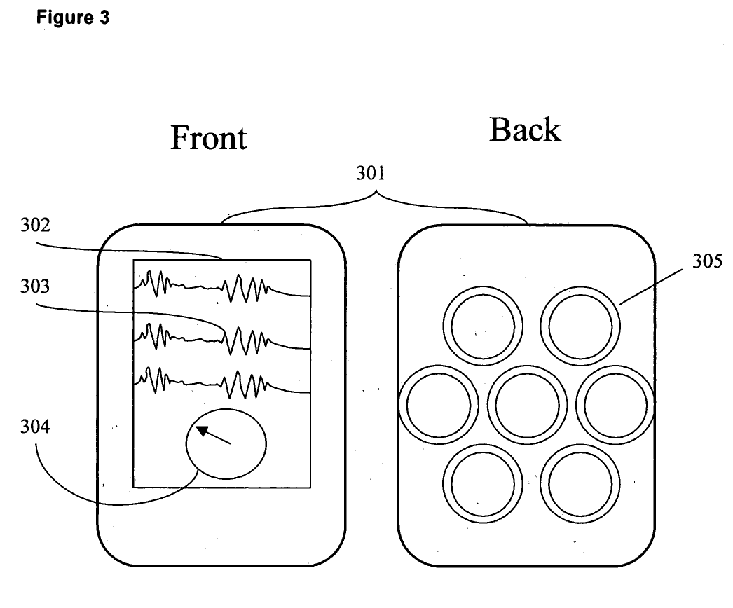

FIG. 3 shows multichannel sound analyzer with seven acoustic sensors 305 mounted on the back of the pocket computer 301. The physician can move the pocket computer around the chest to collect data at different sites. The suitable acoustic sensor can be an omnidirectional electret microphone embedded into the chest piece 305. The multichannel sound analyzer allows a medical practitioner to avoid application of separate acoustic sensors. The result is a faster and less cumbersome procedure.

The pocket computer 301 of the multichannel sound analyzer can be a PDA such as a Compaq iPAQ5450 Pocket PC. The electrical signal from the acoustic sensors is transmitted to the PDA's serial or analog input ports. The transmission can be via wire or wirelessly. The PDA is programmed to display the acoustic waveforms 303 and sound source location 304 on its screen 302 and to store the data for later retrieval/transfer. Also, the PDA can be programmed to perform the automatic analysis of the acoustic signals.

1. A physiological data recording apparatus comprised of:
(a) a pocket computer with display on the front,
(b) one or more sensors mounted on the back of said pocket computer,
(c) means to physically connect said sensors and said pocket computer,
(d) means for physiological signal amplification, filtering, and transmission from said sensors to said pocket computer,
whereby said apparatus can be single handedly pressed by an operator against patient's body in such a manner that sensors are in contact with patient's body and visual display is directed toward the operator.

2. The apparatus of claim 1 wherein said sensors and said pocket computer are physically connected reversibly or irreversibly.

3. The apparatus of claim 1 wherein the electrical signal from said sensors is transmitted to said pocket computer via a wire or wirelessly.

4. The sensors of claim 1 are selected from a group consisting of electroconductive sensors such as EKG sensors, acoustic sensors, optical sensors, infrared sensors, radiofrequency sensors, and other physiological sensors.

5. The pocket computer of claim 1 is selected from a group consisting of a Personal Digital Assistant (PDA), a Windows Pocket PC, a Palm handheld computer, a notebook PC, a tablet PC, a mobile phone, and any other pocket computer.

6. The apparatus of claim 1 incorporating means for visualization of EKG, audio, and other physiological signal waveforms on the computer screen of claim 1.

7. The apparatus of claim 1 incorporating means for automatic identification and marking phases of respiratory cycle, automatic identification and marking events on EKG, and automatic identification and marking heart and lung sounds components.

8. The apparatus of claim 1 having means for automated intrathoracic localization of normal and abnormal lung and heart sounds and visualization of sound sources on the computer display.

9. The pocket computer of claim 1 transmitting data to a secondary computing device, such as a server either via wire or wirelessly.
